(19) United States
(12) Patent Application Publication
(10) Pub. No.: US 2011/0190927 A1
(43) Pub. Date: Aug. 4, 2011

(54) SUBSTRATE CARRYING DEVICE, SUBSTRATE CARRYING METHOD AND STORAGE MEDIUM

(75) Inventor: Yuichi DOUKI, Koshi-Shi (JP)

(73) Assignee: Tokyo Electron Limited, Minato-Ku (JP)

(21) Appl. No.: 13/014,143

(22) Filed: Jan. 26, 2011

(30) Foreign Application Priority Data
Feb. 4, 2010 (JP) 2010-023502

(51) Int. Cl. H01L 21/677; G06F 7/00; H01L 21/673

(52) U.S. Cl. 700/228; 414/222.01; 414/806

(57) ABSTRACT

A substrate carrying device decides whether or not a substrate received from a substrate supporting device is supported therein in a correct position. A support arm provided with support lugs and strain gages attached to the support lugs, respectively, is advanced to a forward position, and then the support arm is raised relative to lifting pins supporting a wafer to receive the wafer from the lifting pins. The strain gages measure strains produced in the support lugs, respectively, when load is placed on the support lugs. Decision about whether or not the wafer is supported in a correct position on the support lugs is made on the basis of strains measured by the strain gages. When it is decided that the wafer is supported in an incorrect position on the support lugs, the retraction of the support arm is inhibited.

### BACKGROUND OF THE INVENTION

1. Field of the Invention

The present disclosure relates to a substrate carrying device and a substrate carrying method for transferring a substrate to and receiving a substrate from a substrate supporting device and to a storage medium.

2. Description of the Related Art

A substrate processing system for manufacturing semiconductor devices or LCD boards has a plurality of modules. A substrate carrying device carries substrates sequentially to the modules to subject the substrates to predetermined processes. As shown by way of example in FIG. 13, the substrate carrying device has a base 13 and forked support arms 11 and 12 capable of longitudinally moving along the base 13. The base 13 can turn about a vertical axis and can move vertically.

As shown in FIGS. 13 and 14, the substrate carrying device is provided with an optical sensor 14 for determining whether or not the support arm 11 (support arm 12) has received a wafer W from the module. The modules include heating modules which processes a wafer W at a high temperature, such as a temperature on the order of 300° C. Since the optical sensor 14 cannot withstand an atmosphere of such a high temperature, the optical sensor 14 is mounted on a sensor holder 15 at a position corresponding to the forward end of the base 13.

In the substrate carrying device shown in FIGS. 13 and 14, the optical sensor 14 detects a wafer W supported on a forked end of the support arm 11 (support arm 12) when the support arm 11 (support arm 12) is retracted to the base end of the base 13. The optical sensor 14 has a light projector 14a and a light receiver 14b. When a wafer W is supported on the support arm 11 as shown in FIG. 14A, the light receiver 14b receives light projected by the light projector 14a and reflected by the wafer W and gives a wafer detection signal. When any wafer is not supported on the support arm 11 (support arm 12) as shown in FIG. 14B, the light receiver 14b cannot receive the light projected by the light projector 14a and does not give any wafer detection signal. Thus, it can be decided whether or not a wafer W is supported on the support arm 11 or 12.

Since the optical wafer detector 14 decides whether or not a wafer W is supported on the support arm 11 (support arm 12) upon the arrival of the support arm 11 (support arm 12) at the base end of the base 13, the support arm 11 (support arm 12) is retracted before it is decided whether or not the support arm 11 (support arm 12) received a wafer W normally. Even if a wafer W is broken or is displaced from a correct transfer position in the module and the wafer W is supported incorrectly on the support arm 11 (support arm 12), the support arm 11 (support arm 12) incorrectly supporting the wafer W continues moving backward. Therefore, there is the possibility that the wafer W falls off the support arm 11 (support arm 12) while the support arm 11 (support arm 12) is moving backward and the fallen wafer W breaks or damages the substrate carrying device.

When the substrate carrying device has the foregoing construction, it is impossible to decide time trouble occurred immediately after it has been decided that any wafer is not supported on the support arms 11 support arm 12). The trouble that any wafer is not supported on the support arm 11 (support arm 12) occurs in the module when a wafer W is transferred between the module and the support arm 11 (support arm 12) or while a wafer W is being carried. However, since the support arm 11 (support arm 12) of the substrate carrying device of the foregoing construction continues moving backward even if the trouble occurs in the module, conditions immediately after the occurrence of the trouble cannot be examined and it is difficult to find out the causes of the trouble.

Accordingly, it has been desired to develop a substrate carrying device provided with support arms 11 and 12 and capable of deciding whether or not a wafer W is supported correctly on the support arm 11 (support arm 12) at the time the support arm 11 (support arm 12) receives the wafer W from the module.

There is a growing tendency to stack up modules in layers in the recent years for the purpose of increasing throughput. When many modules are stacked up, an actual transfer position where a wafer W is transferred between the module and the support arm 11 (support arm 12) in some modules does not coincide with a true transfer position specified by design data due to assembly errors. When trouble is caused by the substrate carrying device, the substrate carrying device is repaired and then, in some cases, a design transfer position in each module is taught to the substrate carrying device. Thus, a transfer position for every module needs to be taught to the substrate carrying device. Usually, teaching work for teaching a transfer position to the substrate carrying device needs a teaching jig. Setting the teaching jig in and removing the setting jig from each module requires troublesome work and needs much time and labor. A substrate carrying device to which a transfer position can be taught without using any jig will be practically useful and convenient.

A gripper arm mentioned in JP-A2000-34016 is provided with gripping fingers capable of moving radially inward to grip a wafer by the edge, support lugs respectively supporting the gripping fingers, and a strain gage attached to one of the support lugs. This gripper arm decides whether or not the gripping arms are correctly gripping a wafer by the edge on the basis of a signal provided by the strain gage. Theoretically, it is possible for the gripper arm to use the strain gage for measuring the height of a wafer W and to change the height of the gripper arm gradually before the wafer W is transferred to the module. Practically, such an operation is very complicated and not practically applicable.

### SUMMARY OF THE INVENTION

Accordingly, it is an object of the present disclosure to provide techniques capable of surely deciding whether or not a substrate is received from a substrate supporting device in a correct position.

A substrate carrying device according to the present disclosure includes: a base capable of being driven by a driving unit for vertical movement; a substrate support arm mounted on the base, capable being driven by a driving unit for longitudinal movement along the base, and shaped so as to surround a substrate; three or more support members arranged at intervals along an inner edge of the substrate support arm and projecting inward from the inner edge of the substrate support arm to support a substrate thereon; strain gages attached to the support members, respectively, to measure strains respectively produced in the support members when downward load is placed on the support members; a decision means for deciding whether or not a substrate is supported in a correct position on the support members on the basis of strains respectively produced in the support members and measured by the strain gages when the substrate is transferred from a substrate supporting device to the support members by advancing the substrate support arm and raising the base relative to the substrate supporting device supporting the substrate; and a retraction inhibiting means for inhibiting the retraction of the substrate support arm when it is decided that the substrate is supported incorrectly on the support members.

A substrate carrying method according to the present disclosure to be carried out by a substrate carrying device comprising: a base capable of being driven by a driving unit for vertical movement; a substrate support arm mounted on the base, capable being driven by a driving unit for longitudinal movement along the base, and shaped so as to surround a substrate; three or more support members arranged at intervals along the inner edge of the substrate support arm and projecting inward from the inner edge of the substrate support arm to support a substrate thereon; to transfer a substrate from and to a substrate supporting device for supporting a substrate thereon; including the steps of: receiving a substrate from the substrate supporting device by advancing the substrate support arm and raising the base relative to the substrate supporting device; measuring strains respectively produced in the support members by strain gages attached to the support members, respectively, when a load is placed on the support members; deciding whether or not the substrate is supported in a correct position on the support members on the basis of strains measured by the strain gages; and inhibiting the retraction of the substrate support arm when it is decided that the substrate is supported in an incorrect position on the support members.

A storage medium according to the present disclosure storing computer programs to be executed by a substrate carrying device including: a base capable of being moved vertically by a driving unit; a substrate support arm shaped so as to surround a substrate, mounted on the base and capable of being driven by a driving unit for longitudinal movement along the base; and three or more support members arranged at intervals along the inner edge of the substrate support arm and projecting inward from the inner edge of the substrate support arm to support a substrate thereon; specifying sets of instructions to be executed in the steps of the substrate carrying method of the present disclosure.

According to the present disclosure, the strain gages attached respectively to the support members measure strains respectively produced in the support members when a substrate is transferred from the substrate supporting device to the support members and a decision whether or not the substrate is supported in a correct position on the support members is made on the basis of the strains measured by the strain gages. Thus, whether or not the substrate received from the substrate supporting device is supported in a correct position on the support members can be surely and easily decided.

### BRIEF DESCRIPTION OF THE DRAWINGS

FIG. 1 is a schematic plan view of a resist pattern forming system provided with wafer carrying devices in a preferred embodiment according to the present disclosure;

FIG. 2 is a schematic perspective view of the resist pattern forming system shown in FIG. 1;

FIG. 3 is a schematic sectional view of the resist pattern forming system shown in FIG. 1;

FIG. 4 is a schematic perspective view of a third block included in the resist pattern forming system shown in FIG. 1;

FIG. 5 is a perspective view of the wafer carrying device installed in the third block shown in FIG. 4;

FIG. 6 is a plan view of the wafer carrying device shown in FIG. 5;

FIG. 7 is a circuit diagram of a strain measuring circuit included in the wafer carrying device shown in FIG. 5;

FIG. 8 is a block diagram of a controller included in the resist pattern forming system shown in FIG. 1;

FIGS. 9A to 9D are schematic sectional views of assistance in explaining operations of the resist pattern forming system shown in FIG. 1;

FIGS. 10A to 10C are a plan view, a front elevation and a plan view, respectively, of a wafer support arm included in the wafer carrying device shown in FIG. 5 in a state where a wafer is supported in an incorrect position on the wafer support arm;

FIGS. 11A and 11B are plan views of the wafer support arm in a state where a wafer is supported in an incorrect position;

FIGS. 12A to 12D are graphs of assistance in explaining characteristics of a strain gage;

FIG. 13 is a perspective view of a prior art substrate carrying device; and

FIGS. 14A and 14B are schematic side elevations of the prior art substrate carrying device.

### DESCRIPTION OF THE PREFERRED EMBODIMENTS

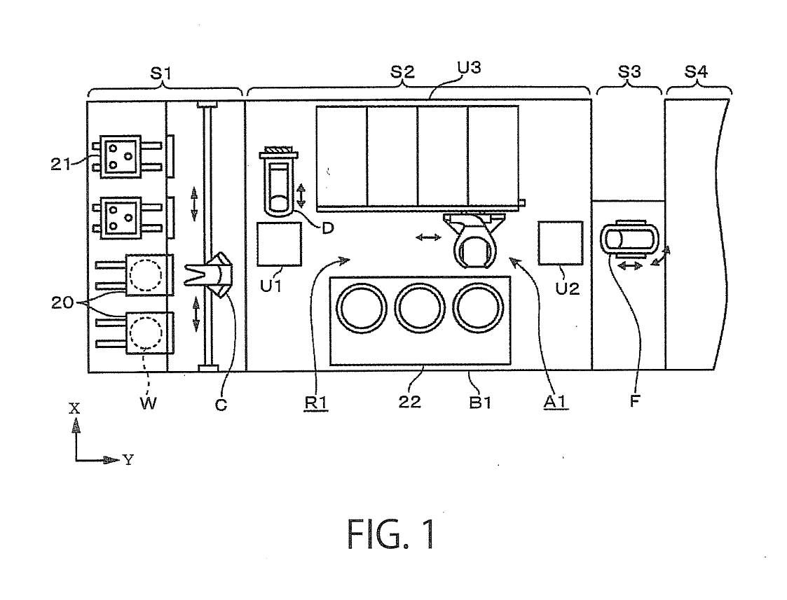

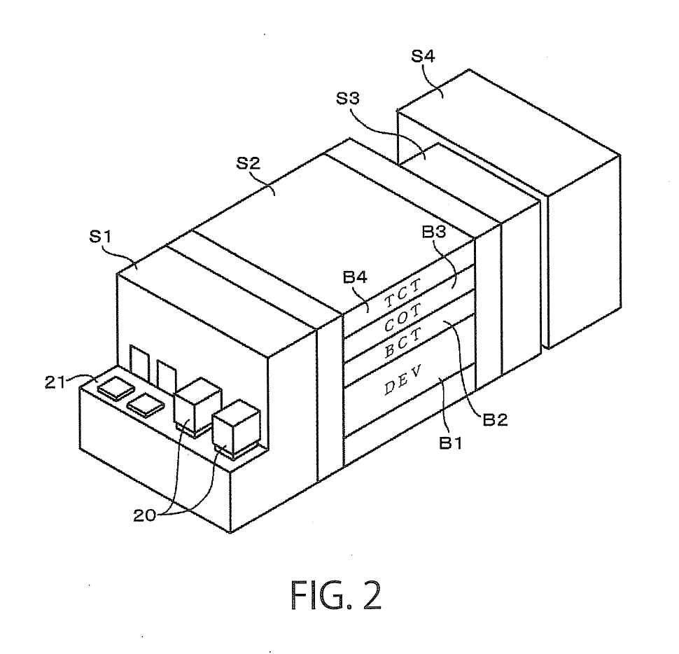

A substrate processing system provided with wafer carrying devices in a preferred embodiment according to the present disclosure will be described as applied to a coating and developing system. A resist pattern forming system built by combining an exposure system with the coating and developing system will be briefly described with reference to the accompanying drawings. FIGS. 1 and 2 are a schematic plan view and a schematic perspective view, respectively, of a resist pattern forming system provided with wafer carrying devices in a preferred embodiment according to the present disclosure. The resist pattern forming system has a carrier block S1, a processing block S2 and an interface block S3. An airtight carrier 20 is delivered to a carrier table 21 disposed in the carrier block S1. A transfer device C takes out a wafer W from the carrier 20 and transfers the same to the processing block S2 adjacent to the carrier block S1. The transfer device C receives a processed wafer W from the processing block S2 and returns the same to the carrier 20.

Referring to FIG. 2, the processing block S2 has a first block B1 (DEV layer B1) for processing a wafer W by a developing process, a second block S2 (BCT layer S2) for forming an antireflection film beneath a resist film, a third block S3 (COT layer S3) for forming a resist film, and a fourth block S4 (TCT layer S4) for forming an antireflection film on a resist film. The blocks S1, S2, F3 and S4 are stacked up in that order.

Each of the second block B2 (BCT layer B2) and the fourth block B4 (TCT layer 84) has coating modules for coating a wafer W with an antireflection film forming solution by a spin coating method, heating-and-cooling modules for processing a wafer W by a pretreatment before processing the wafer by the coating module and by a posttreatment after the wafer W has been processed by the coating module, and wafer carrying devices A2 and A4 installed between the group of the coating modules and the group of the heating-and-cooling modules to transfer a wafer from and to those modules. The third block B3 (COT layer 83) provided with a wafer carrying device A3 is the same in construction as the second block B2 and the fourth block 84, except that the third block 83 uses a resist solution instead of the antireflection film forming solution.

The first block B1 (DEV layer 81) has developing modules 22 stacked up in two layers and one wafer carrying device A1 for carrying wafers W to the developing modules 22 stacked up in two layers. The wafer carrying devices A1 to A4 correspond to a substrate carrying device of the present disclosure.

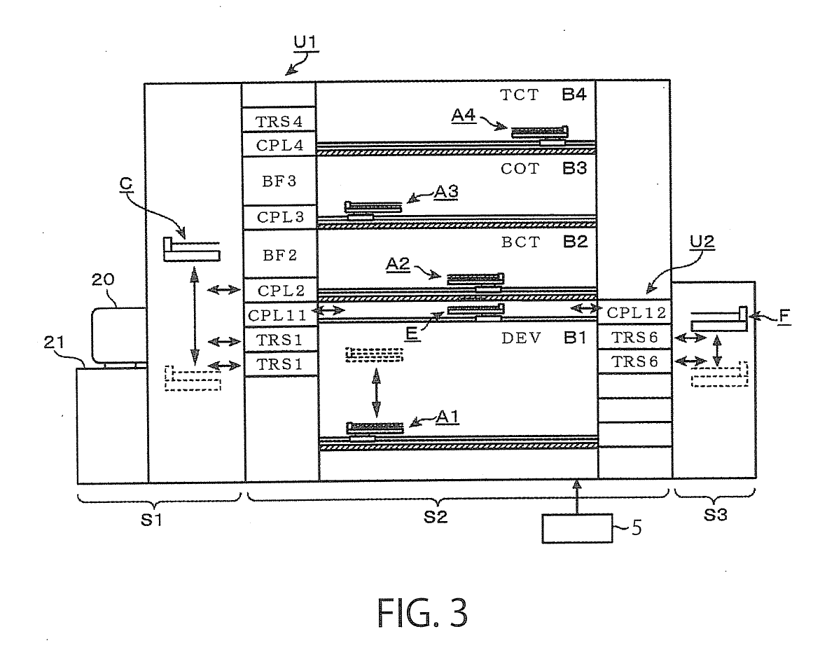

Referring to FIGS. 1 and 3, a shelf unit U1 is installed in the processing block S2. A vertically movable transfer arm D disposed near the shelf unit U1 carries a wafer W to and from parts of the shelf unit U1. Wafers W received from the carrier block S1 are carried sequentially by the transfer device C to one of the transfer modules of the shelf unit U1, such as a transfer module CPL 2 corresponding to the second block B2 (BCT layer B2). The wafer carrying device A2 installed in the second block 82 (BCT layer 82) receives the wafer W from the transfer module CPL2 and carries the same to the processing modules, namely, the antireflection film forming module and the heating-and cooling module, to form an antireflection film on the wafer W.

The wafer W is carried through a transfer module BF2 of the shelf unit U1, the transfer arm D, a transfer module CPL3 of the shelf unit U1, and the wafer carrying device A3 to the third block 83 (COT layer B3). A resist film is formed on the wafer W by the third block B3 (COT layer B3). The wafer carrying device A3 carries the wafer W coated with the resist film to a transfer module BF3 of the shelf unit U1. In some cases, an antireflection film is formed by the fourth block 84 (TCT layer B4) on the resist film coating the wafer W. In such a case, the wafer W is transferred through a transfer module CPL4 to the wafer carrying device A4. After an antireflection film has been formed on the resist film formed on the wafer W, the wafer carrying device A4 carries the wafer W to a transfer module TRS4.

A shuttle carrier E is installed in an upper space in the DEV layer B1. The shuttle carrier E is used exclusively for carrying a wafer W from a transfer module CPL11 included in the shelf unit U1 directly to a transfer unit CPL12 included in a shelf unit U2. A wafer W provided with a resist film and an antireflection film is transferred through the transfer modules BF3 and TRS4 to the transfer module CPL11 by the transfer arm D. The shuttle carrier E carries the wafer W directly to the transfer module CPL12 of the shelf unit U2. Then the wafer W is delivered to the interface block S3. In FIG. 3, transfer modules CPL serve also as cooling modules for adjusting the temperature of a wafer W and transfer modules BF serve also as buffer modules each capable of holding a plurality of wafers W.

Subsequently, an interface arm F carries the wafer W to the exposure system S4 to subject the wafer W to a predetermined exposure process. After the wafer W has been processed by the exposure process, the wafer W is returned through a transfer module TRS6 to the processing block S2. Then, the wafer W is processed by a developing process in the first block B1 (DEV layer B1). Then, the wafer carrying device A1 carries the wafer W to the transfer module TRS1 within reach of the transfer device C and the wafer W is returned to the carrier 20 by the transfer device C.

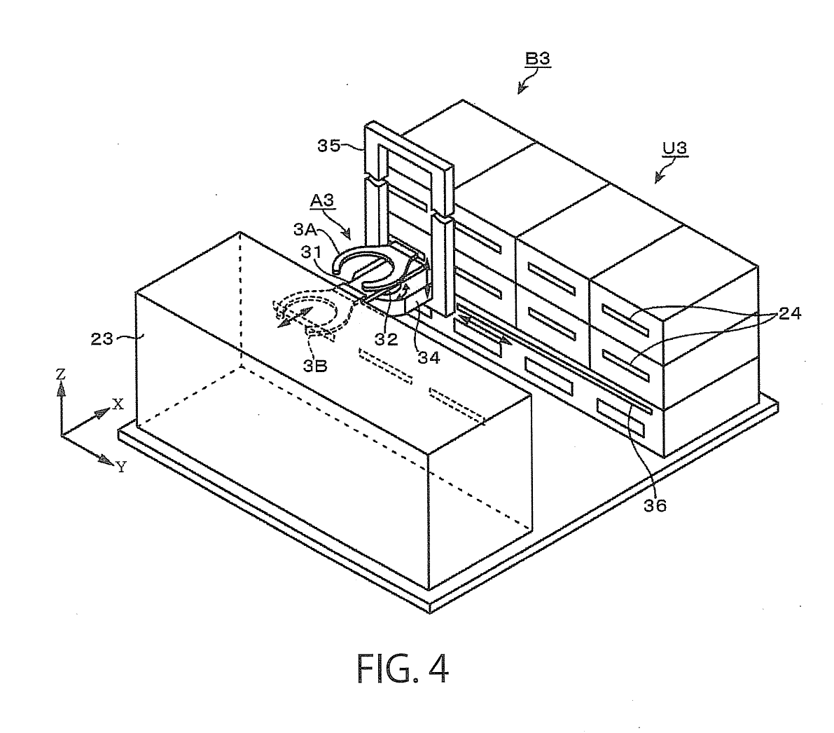

FIG. 4 is a schematic perspective view of the third block B3 (COT layer B3). Indicated at U3 in FIGS. 1 and 4 is a shelf unit built by stacking up a plurality of modules including heating modules and cooling modules. The shelf unit U3 is disposed opposite to coating modules 23. The wafer carrying device A3 is installed in a space between the shelf unit U3 and the row of the coating modules 23. In FIG. 4, indicated at 24 are openings through which the wafer carrying device A3 carries a wafer W into and carries out a wafer W from the modules.

The wafer carrying devices A1 to A4 will be described. Since the wafer carrying devices A1 to A4 are the same in construction, the wafer carrying device A3 installed in the third block Be (COT layer B3) will be described by way of example. Referring to FIGS. 4 to 6, the wafer carrying device A3 has a plurality of forked support arms 3, two support arms 3A and 3B in this embodiment, and a base 31. The support arms 3A and 3B can move longitudinally along the X-axis shown in FIG. 4 on the base 31. The base 31 can be turned about a vertical axis by a turning mechanism 32. The support arms 3A and 3B have base ends supported on wafer carrying device moving mechanisms 33A and 33B, respectively. The wafer carrying device moving mechanisms 33A and 33B are driven for movement along the base 31 by a drive mechanism, not shown, placed in the base 31 and including timing belts.

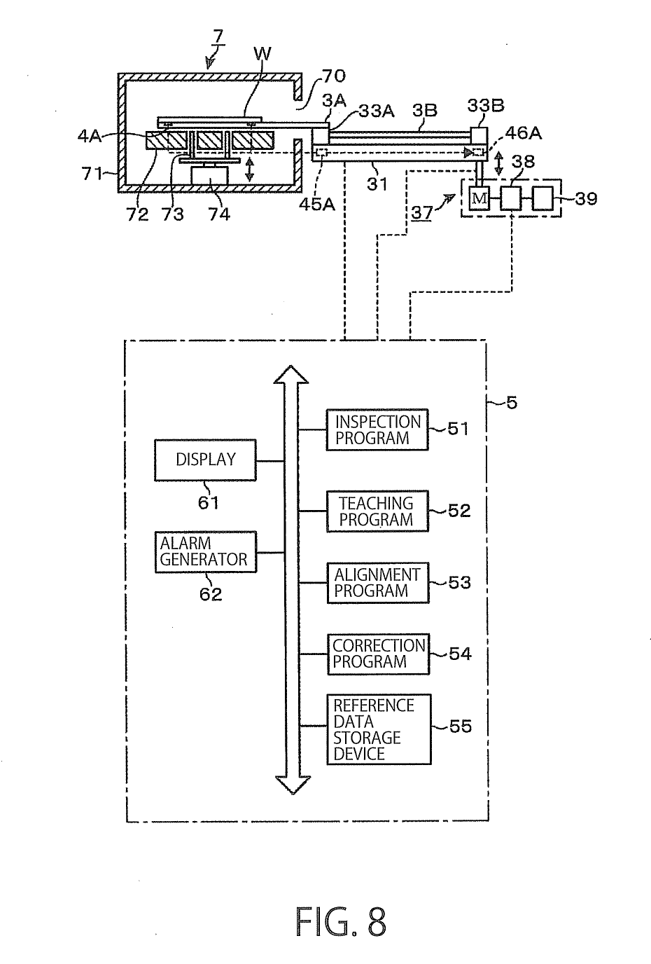

A lifting table 34 is placed under the turning mechanism 32. The lifting table 34 is moved vertically by a lifting mechanism 37 (FIG. 8) along vertical, straight Z-axis guide rails, not shown, extended parallel to the Z-axis shown in FIG. 4. The lifting mechanism 37 may be a generally known mechanism, such as a ball screw or a belt drive mechanism including a timing belt. The ball screw or the belt drive mechanism is driven by a motor M to move the lifting table 34 vertically. In this embodiment, the Z-axis guide rails and the lifting mechanism 37 are covered with covers 35. Upper ends of the covers 35 are connected by a connector. The covers 35 slides along a straight, Y-axis guide rail extended parallel to the Y-axis.

In FIG. 8, the lifting table 34 is omitted and only the lifting mechanism 37 is shown below the base 31 for convenience. The lifting mechanism 37 moves the base 31 along the Z-axis guide rails when a lifting shaft, not shown, extended in the Z-axis guide rails is driven for rotation by the motors M. The motor M is connected to an encoder 38. In FIG. 8, indicated at 39 is a counter for counting pulses generated by the encoder 38.

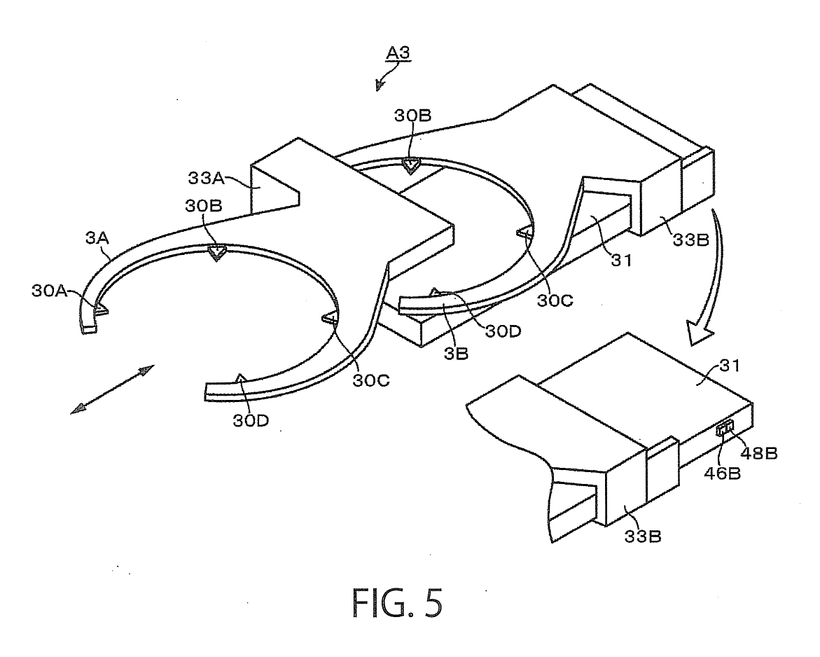

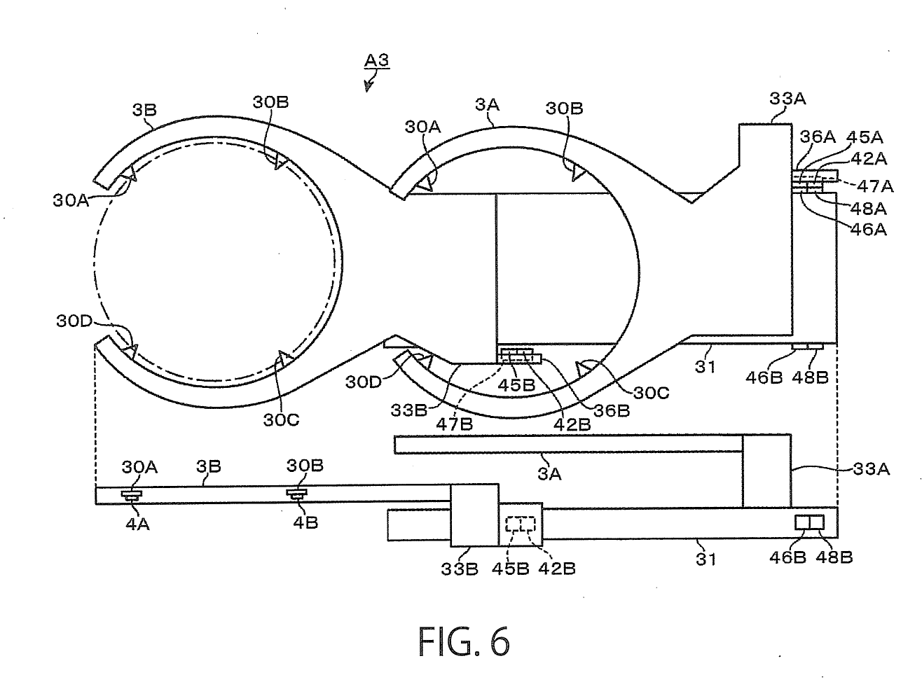

Referring to FIGS. 5 and 6, the forked support arms 3A and 3B are formed in a substantially circular shape. Three or more support lugs 30 are arranged at circumferential intervals along the inner edge of each of the support arms 3A and 3B so as to project inward. A circumferential edge part of a wafer W is seated on the support lugs 30. In this embodiment, four support lugs 30A, 30B, 30C and 30D are arranged at circumferential intervals along the inner edge of each of the support arms 3A and 3B to support a wafer W by the four parts at four positions in the circumferential edge part of the wafer W. Strain gages 4A, 4B, 4C and 4D are attached to the support lugs 30A to 30D, respectively. The strain gages 4A to 4D measure strains respectively produced in the support lugs 30A to 30D when downward load is placed on the support lugs 30A to 30D. In this embodiment, the strain gages 4A to 4D are attached to the back surfaces of the support lugs 30A to 30D, respectively. The strain gages 4A to 4D may be embedded in the support lugs 30A to 30D, respectively.

Each of the strain gages 4A to 4D has a thin insulating sheet and a thin metallic resistor wire extended in a predetermined pattern on the thin insulating sheet. For example, the thin insulating sheets are adhesively attached to the back surfaces of the support lugs 30A to 30D, respectively, with an adhesive. Changes in electric resistance of the metallic resistor wires resulting from the straining of the support lugs 30A to 30D are measured to determine strains respectively produced in the support lugs 30A to 30D. When the support lugs 30A to 30D are stained, the strain gages 4A to 4D are strained accordingly. When the strain gages 4A to 4D are thus strained, the electric resistances of the strain gages 4A to 4D increase. Increases in the electric resistances of the strain gages 4A to 4D are measured. Since each of the strain gages 4A to 4D has a very low resistance, the increase in the electric resistance of each of the strain gages 4A to 4D is converted into a voltage by a Wheatstone bridge.

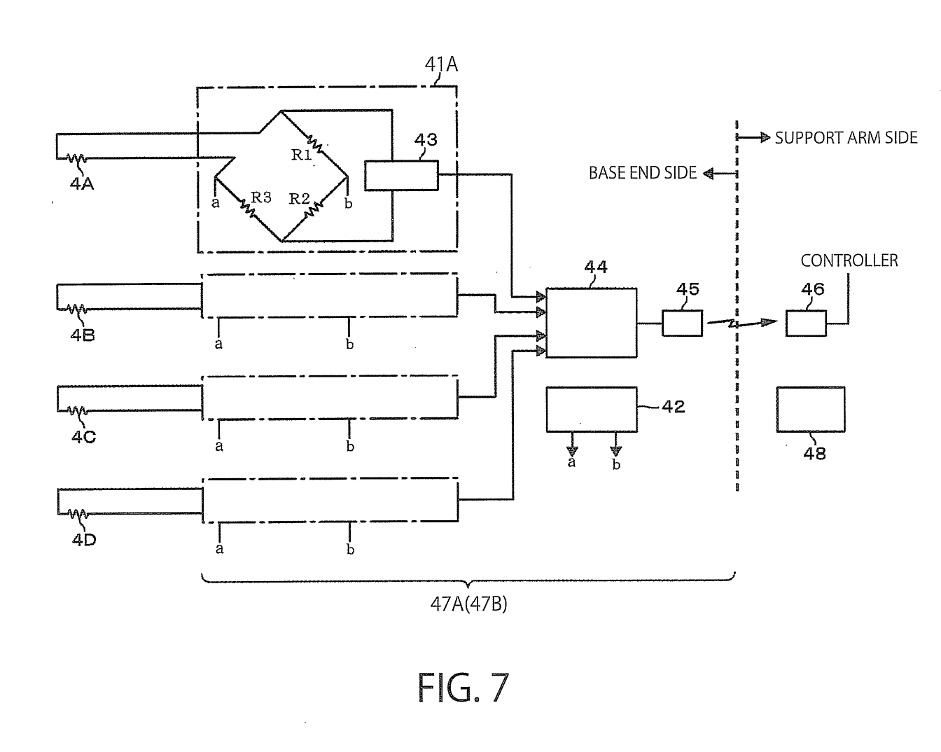

More concretely, Wheatstone bridges are formed by connecting the strain gages 4A to 4D to sensing circuits 41A, 41B, 41C and 41D, respectively, as shown in FIG. 7. When a battery 42 applies an input voltage to the Wheatstone bridges, the respective output voltages of the Wheatstone bridges are measured by voltmeters 43. The voltmeters 43 send measured output voltages representing strains to a signal processing unit 44. The signal processing unit 44 is provided with A/D converters for channels connected to the sensing circuits 41A to 41D, respectively, and a power supply PS. The signal processing unit 44 sends voltage signals transmitted by the channels in a serial fashion through a transmitter 45 to a receiver 46 mounted on the base 31.

The sensing circuits 41A to 41D, the battery 42, the signal processing unit 44, the transmitter 45 are integrated into a circuit unit 47A (circuit unit 47B) for the support arm 3A (support arm 3B). The receiver 46 and a charger 48 for charging the battery 42 of the circuit unit 47A (circuit unit 47B) are prepared for the support arm 3A (support arm 3B) and is mounted on the base 31.

In this embodiment, the circuit unit 47A (circuit unit 47B) is mounted on a base end part of the support arm 3A (support arm 3B). For example, the circuit unit 47A (circuit unit 47B) is mounted on a bracket 36A (bracket 36B) protruding from a side part of the carrying device moving mechanism 33A (carrying device moving mechanism 33B) for longitudinally moving the support arm 3A (support arm 3B). Wiring for the sensing circuits 41A to 41D of the circuit unit 47A (47B) and the strain gages 4A to 4D is laid in the support arm 3A (support arm 3B).

The receiver 46A (receiver 46B) is attached to a side surface of a base end part of the base 31 for the support arm 3A (support arm 3B). Chargers 48A and 48B respectively for the support arms 3A and 3B are attached to the base 31. In this embodiment, the strain gages 4A to 4D measure strains when the support arm 3A (support arm 3B) is protruded forward from the base 31. The transmitter 45A (transmitter 45B) sends signals representing measured strains to the receiver 46A (46B) by known communication means, such as infrared communication means or radio communication means. When the support arm 3A (support arm 3B) is advanced toward the front end of the base 31 to a transfer position, the transmitter 45A (transmitter 45B) of the circuit unit 47A (47B) and the receiver 46A (46B) are on a straight line. Then, the transmitter 45A (transmitter 45B) transmits signals to the receiver 46A (46B) in a noncontact transmission mode.

The receiver 46A (46B) for the support arm 3A (support arm 3B) may be disposed on a front part of the side surface of the base 31 such that the transmitter 45A (transmitter 45B) of the circuit unit 47A (47B) is positioned opposite to the receiver 46A (receiver 46B) when the support arm 3A (support arm 3B) is positioned at the transfer position, namely, a forward position. In such a case, signals may be transmitted from the transmitter 45A (transmitter 45B) to the receiving unit 46A (46B) in a state where the transmitter 45A (transmitter 45B) is in contact with or close to the receiver 46A (receiver 46B)

In this embodiment, the charger 48A (charger 48B) comes into contact with the battery 42A (42B) of the circuit unit 47A (46B) to charge the battery 42A (42B) when the support arm 3A (support arm 3B) is retracted to an idle position in a rear end part of the base 31.

A controller 5 included in the resist pattern forming system will be described with reference to FIG. 8. The controller 5 is, for example, a computer having a data processing unit provided with programs, memories and a CPU. The programs are sets of instructions for the computer to execute to make the controller 5 send control signals to the component parts of the resist pattern forming system to carry out a resist pattern forming processes and wafer transfer inspecting processes. The programs are stored in a storage medium, such as a flexible disk, a compact disk, a hard disk or a magnetooptical disk. The storage medium is loaded into the controller 5.

The programs include an inspection program 51 to be executed in an inspection mode, a teaching program 52 to be executed in a teaching mode, and an alignment program 53 to be execute in an alignment mode. The controller 5 has a reference data storage device 55. Predetermined control signals are sent to the receivers 46A and 46B mounted on the base 31, a display 61 connected to the computer, an alarm generator 62, support arm moving mechanisms 33A and 33B for moving the wafer carrying devices A1 to A4, the motor M of the driving mechanism, the encoder 38 and the counter 39.

For example, the display 61 is incorporated into the computer and is used for choosing the inspection mode, the alignment mode or the teaching mode. The display is used for choosing a predetermined wafer processing process and an inspection process and entering parameters for those processes. Results of inspection and alignment information are displayed by the display 61.

The inspection program 51 is a set of instructions for deciding whether or not a wafer W received from the substrate supporting device by the support arm 3A (support arm 38) is supported in a correct position on the support arm 3A (support arm 3B) on the basis of strains produced in the support lugs 30A to 30D and measured by the strain gages 4A to 4D, and controlling operations for driving the wafer carrying devices A1 to A4. A threshold determined on the basis of strains measured by the strain gages 4A to 4D (voltages) when a wafer W is supported in a correct position on the support lugs 30A to 30D is stored as reference date in the reference data storage device 55. The weight of a wafer W changes as the wafer W is processed. Therefore, the reference data stored in the reference data storage device 55 includes values of the weight of a wafer W after being processed by the processes.

Decision instructions of the inspection program 51 are executed to compare strains measured by the strain gages 4A to 4D with the reference data, namely, the threshold, to decide that a wafer W is supported in an incorrect position when at least one of the strains is below the threshold, to give a carrying operation continue instruction to the wafer carrying devices A1 to A4 when a wafer W is supported in a correct position by the support arm 3A (support arm 3B)), and to give a retraction inhibition instruction to the wafer carrying device A1 (carrying device A2, A3 or A4) and an alarm indication instruction when a wafer W is supported in an incorrect position on the support arm 3A (support arm 3B). Alarm indication is achieved by lighting up an alarm lamp or sounding an alarm signal, i.e., actuating the alarm generator 61, or displaying an alarm by the display 61 of the computer.

The teaching program 52 is a set of instructions to be executed to execute operations in a teaching mode to teach transfer operations for transferring a wafer W from the support arm 3A (support arm 3B) to the substrate supporting device and from the substrate supporting device to the support arm 3A (support arm 3B). The alignment program 53 is a set of instructions to be executed to carry out operations in an alignment mode to determine the position of a wafer W on the support lugs 30A to 30D when the wafer W is transferred from the substrate supporting device to the support arm 3A (support arm 3B). Those programs will be described later.

Operations in the inspection mode will be described. The inspection mode is chosen when a wafer W is processed by regular processes. The inspection mode is chosen automatically or may be chosen by operating the display 61 when a wafer W is to be processed by regular processes. The inspection program 51 is executed when the inspection mode is chosen.

Operations for transferring a wafer between the support arm 3A and the heating module for a heat treatment will be described by way of example. As mentioned above, the heating modules are included in the shelf unit U3 in each of the first block B1 (DEV layer B1), the second block B2 (BCT layer B2), the third block B3 (COT layer B3) and the fourth block B4 (TCT layer B4).

Referring to FIG. 8, the heating module has a furnace 71, a heating plate 72 placed in the furnace, lifting pins 73 which are raised to lift up a wafer W and lifting mechanism 74 for vertically moving the lifting pins 73. When a wafer W is to be transferred from the support arm 3A (support arm 3B) to the heating plate 72, the lifting pins 73 are raised to an upper position above the heating plate 72, the support arm 3A (support arm 3B) supporting the wafer W is advanced to a forward position above the raised lifting pins 73, and then the support arm 3A (support arm 3B) is lowered to the transfer position to transfer the wafer W to the lifting pins 73. Subsequently, the support arm 3A (support arm 3B) is retracted to the idle position and the lifting pins 73 are lowered to place the wafer W on the heating plate 72. When the wafer W is to be transferred from the heating plate 72 to the support arm 3A (support arm 3B), the lifting pins 73 are raised to the upper position to lift up the wafer W from the heating plate 72, the support arm 3A (support arm 3B) is advanced to the forward position below the wafer W, and then the support arm 3A (support arm 3B) is raised to the transfer position to receive the wafer W from the lifting pins 73. The lifting pins 73 correspond to the substrate supporting device. Indicated at 70 in FIG. 8 is an opening through which a wafer W is carried into and carried out of the processing furnace 71.

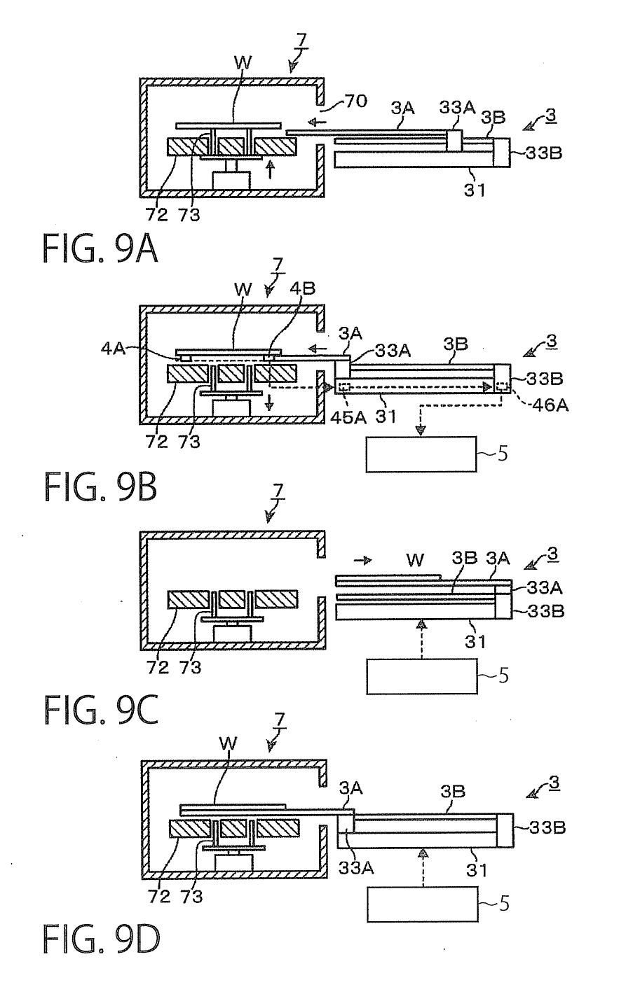

The predetermined reference data is chosen by operating, for example, the display 61 before starting operations for processing wafers. A wafer W is lifted up to the upper position above the heating plate 72 by the lifting pins 73 in the heating module 7 as shown in FIG. 9A. Then, as shown in FIG. 9B, the support arm 3A is advanced to a position below the wafer W, and then the support arm 3A is raised to support the wafer W on the support lugs 30A to 30D. When the wafer W is thus supported on the support lugs 30A to 30D, the support lugs 30A to 30d are strained by the weight of the wafer W. Voltage signal corresponding to strains measured by the four strain gages 4A to 4D, respectively, are generated.

To transfer the wafer W from the lifting pins 73 to the support arm 3A, the support arm 3A advanced to the position below the wafer W is raised to the position above the lifting pins 73. Then, the support arm 3A supporting the wafer W is retracted. The controller 5 is previously notified of time the wafer W is transferred from the lifting pins 73 to the support lugs 73. The controller 5 receives signals corresponding to the strains measured by the strain gages 4A to 4D, for example, at time T₂ 50 ms after time T₁ when the wafer W is transferred from the lifting pins 73 to the support lugs 30A to 30D. The signals corresponding to the strains measured by the strain gages 30A to 30D at time T₂ to ensure that the signals are received after the wafer W has been surely transferred from the lifting pins 73 to the support lugs 30A to 30D. “The time the wafer W is transferred from the lifting pins 73 to the support lugs 30A to 30D” is not only time T₁, but include times in a period from time T₁ to time within 1 s from time T₁.

When the support arm 3A is advanced to the forward position (the transfer position), the transmitter 45A of the circuit unit 47A is separated from the receiver 46A on the base 31. Since the transmitter 47A and the receiver 46A are on a straight line, signals representing the strains measured by the four strain gages 4A to 4D on the support arm 3A are sent through the receiver 46A on the base 31 to the controller 5. In the controller 5, the decision means of the inspection program 51 compares the strains with the threshold and presumes the strains as ON data when the strains are greater than the threshold or as OFF data when the strains are below the threshold.

When all the stains measured by the strain gages 4A to 4D are ON data, it is decided that the wafer W is supported in a correct position on the support arm 3A and the operation for processing the wafer W is continued. In this case, the support arm 3A is retracted to the idle position as shown in FIG. 9C, and then the support arm 3A is moved to the next destination. When the support arm 3A is held at the idle position, the battery 42A on the support arm 3A is connected to the charger 48A on the base 31, so that the battery 42A is charged.

When at least one of the strains measured by the strain gages 4A to 4D is OFF data, it is decided that the wafer W is supported in an incorrect position on the support arm 3A and an alarm instruction requesting alarm generation is given to the alarm generator 62, a signal to inhibit the retraction of the support arm 3A is given to the wafer carrying device A3, and a signal to stop processing the wafer W at the heating module is given.

When the signal to inhibit the retraction of the support arm 3A is given to the wafer carrying device A3, the operation of the wafer carrying device A3 is stopped in a state where the wafer W has been received by the support arm 3A in the heating module 7 as shown in FIG. 9D. Then, the operator tries to find what has caused the wafer W to be supported in an incorrect position on the support arm 3A and executes a recovery operation and maintenance work.

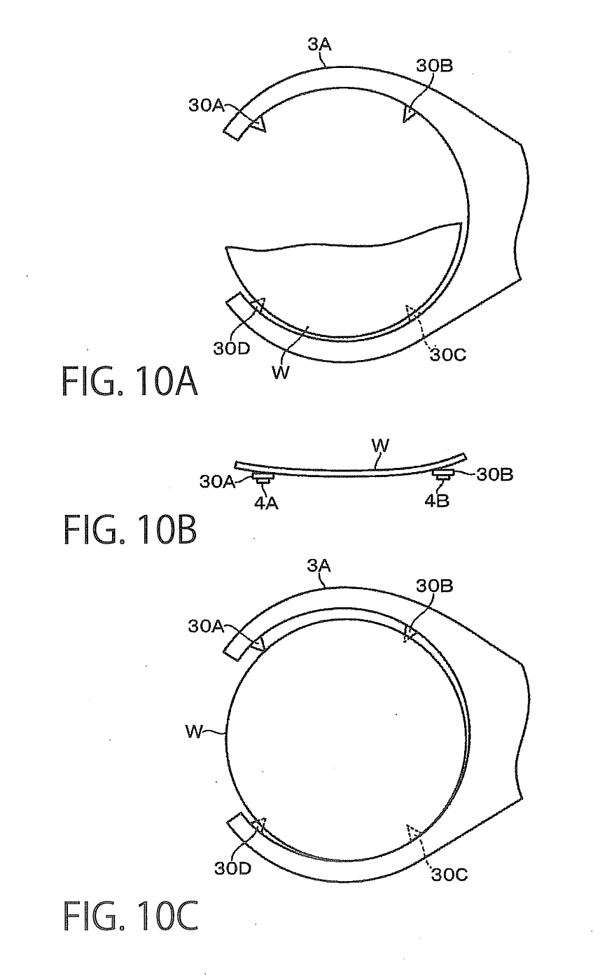

States where wafers W are supported in an incorrect position on the support arm 3A as shown in FIGS. 10A, 10B and 10C will be described by way of example. In the state shown in FIG. 10A, a broken wafer W is supported on the support arm 3A. In the state shown in FIG. 10B, a warped wafer W is supported on the support arm 3A. In the state shown in FIG. 10C, a wafer W is displaced from a correct position on the support lugs 30A to 30D.

When the broken wafer W is supported on the support arm 3A as shown in FIG. 10A, OFF data is obtained from signals provided by the strain gages 4A and 4B attached to the support lugs 30A and 30B not supporting the wafer W. The OFF data indicates an abnormal condition. When the warped wafer W is supported on the support arm 3A as shown in FIG. 10B, the weight of the wafer W is distributed irregularly to the support lugs 30A to 30B; a relatively large weight is placed on the support lug 30A and a relatively small weight is placed on the support lug 30B. While ON data is obtained from a signal provided by the strain gage 4A attached to the support lug 30A, OFF data is obtained from a signal provided by the strain gage 4B attached to the support lug 30B to indicate an abnormal condition.

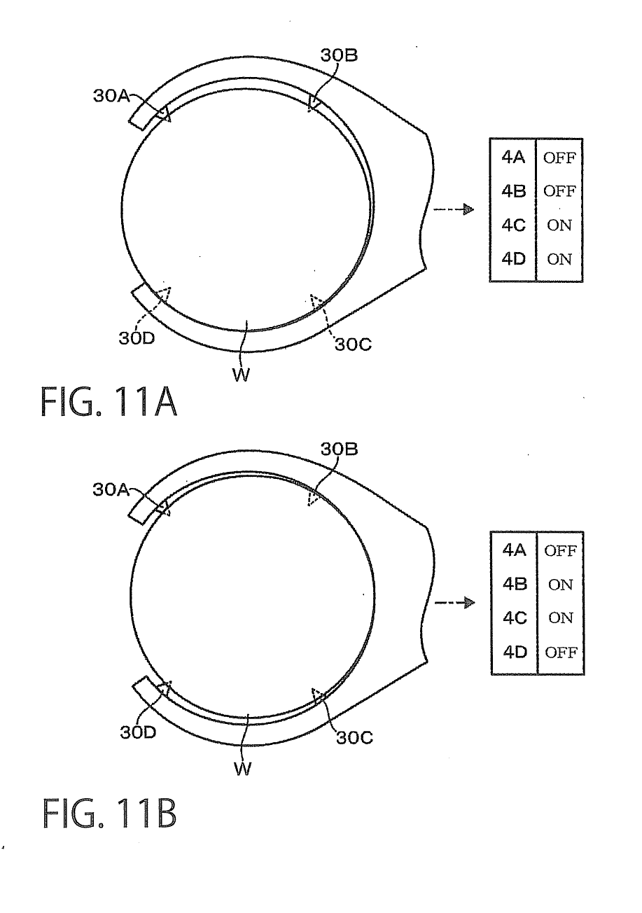

When the wafer W supported on the support lugs 30A to 30D is displaced from a correct position as shown in FIG. 10C, the wafer W is displaced laterally shown in FIG. 11A or the wafer W is displaced longitudinally as shown in FIG. 11B. In such a case, the weight of the wafer W is distributed irregularly to the support lugs 30A to 30D. Consequently, some of strains measured by the strain gages 4A to 4D are below the threshold. When the wafer W is displaced laterally as shown in FIG. 11A, ON data is obtained from signals provided by the strain gages 4C and 4D and OFF data is obtained from signals provided by the strain gages 4A and 4B. Thus, it is decided that the wafer W is supported in an incorrect position on the support arm 3A. When the wafer W is displaced longitudinally, ON data is obtained from signals provided by the strain gages 4B and 4C and OFF data is obtained from signals provided by the strain gages 4A and 4D. Thus, it is decided that the wafer W is supported in an incorrect position on the support arm 3A.

In this embodiment, it is decided whether or not the wafer W is supported in a correct position on the support arm 3A on the basis of strains produced in the support lugs 30A to 30D by the weight of the wafer W distributed to the support lugs 30A to 30D when the wafer W is transferred from the lifting pins 73 to the support lugs 30A to 30D and measured by the strain gages 4A to 4D. Thus, whether or not the wafer W is transferred from the lifting pins 73 to the support lugs 30A to 30D in a correct position can be surely and easily decided.

The strain gages 4A to 4D are superior in heat resistance to optical sensors or the like. Even if the strain gages 4A to 4D are exposed to a high-temperature atmosphere on the order of 350° C. when a wafer W is transferred between the heating module 7 and the support arm 3A, the strain gages 4A to 4D can accurately measure stains produced in the support lugs 30A to 30D by the weight of the wafer W. Therefore, the strain gages 4A to 4D can be attached to the support lugs 30A to 30D, respectively, and whether or not a wafer W received from the lifting pins 73 is supported in a correct position on the support lugs 30A to 30D can be surely decided upon the reception of the wafer W by the support lugs 30A to 30D from the lifting pins 73. The circuit unit 47A (47B) is mounted on the base end part of the support arm 3A (support arm 3B) remote from the high-temperature atmosphere and less subject to a thermal effect than the front end part of the support arm 3A (support arm 3B). Therefore, strains produced in the support lugs 30A to 30D can be accurately measured.

Inhibition of the retraction of the support arm 3A to the idle position when it is decided that a wafer W transferred from the lifting pins 73 to the support lugs 30A to 30D is supported in an incorrect position can avoid secondary trouble. If the support arm 3A supporting a wafer W in an incorrect position is retracted, there is the possibility that secondary trouble, such as fall of the wafer W off the support arm 3A or collision between the support arm 3A and the wafer W fallen off the support arm 3A, arises. The occurrence of such trouble is prevented. Even if a wafer W is transferred in an incorrect position, only the position of the wafer W needs to be corrected by simple measures, and then the process can be resumed as soon as the position of the wafer W has been corrected.

Decision about whether or not a wafer W is supported in a correct position is made upon the transfer of the wafer W from the lifting pins 73 to the support arm 3A. Therefore, when trouble, such as the breakage of a wafer W in the module, occurs, the cause of the trouble can be immediately detected. Since the retraction of the support arm 3A is inhibited when it is decided that a wafer W is in an incorrect position, the condition of the trouble can be preserved and observed, conditions of the support arm 3A and the module immediately after the occurrence of the trouble can be verified. Since whether the trouble is caused by the module or by the transfer of the wafer W between the module and the support arm 3A (support arm 3B) can be easily decided, the reoccurrence of the trouble can be prevented.

A wafer W is transferred from the lifting pins 73 to the support lugs 30A to 30D by a simple operation to lift up the wafer supported on the lifting pins 73 by the support lugs 30A to 30D. Therefore, an external force, which will act on the wafer W when the wafer W is held by pressing the wafer W, will not act on the wafer W. Thus, the wafer W is rarely broken when the wafer W is transferred from the lifting pins 73 to the support lugs 30A to 30D and the condition of the module can be readily known. If a wafer W has been broken or warped before the wafer W is received by the support arm 3A (support arm 3B), it can be easily presumed that trouble is caused by the module and the cause of the trouble can be easily detected. When a wafer W is displaced from a correct position on the support lugs 30A to 30D, the cause of trouble can be cleared up immediately after the occurrence of the trouble. Therefore, decision about whether the module is the cause of the trouble or the wafer carrying device A3 is the cause of the trouble can be easily made. Such a quick decision of the cause of the trouble is effective in preventing the reoccurrence of the trouble.

It is decided that a wafer W is in a correct position when ON data is obtained from strains measured by all the strain gages 4A to 4D in this embodiment. However, when ON data is obtained from strains measured by three ones of the strain gages 4A to 4D, it may be presumed that ON data may be obtained from a strain measured by the rest of the strain gages and may be decided that the wafer W is supported in a correct position.

Decision about whether or not a wafer W is supported in a correct position may be made by determining a proper range of strain on the basis of strains measured by the strain gages 4A to 4D when a wafer W is supported in a correct position on the support lugs 30A to 30D and it may be decided that a measured strain is ON data when the measured strain is in the proper range and that a measured strain is OFF data when the measured strain is outside the proper range.

The teaching mode and the alignment mode will be described. Operations in those modes are executed when it is decided that a wafer W is supported in an incorrect position at the start of the system, during maintenance work or in the foregoing embodiment. Since operations in the inspection mode are executed in a normal state, the operator chooses the teaching mode or the alignment mode by operating the display 61 to start operations in the teaching mode or the alignment mode. Then, the teaching program 52 or the alignment program 53 is read out and the inspection mode is changed for the teaching mode or the alignment mode.

First, the teaching mode will be described. The teaching mode is selected to teach operations for transferring a wafer W between the substrate supporting device and the support lugs 30A to 30D.

The teaching program 53 is designed so as to read a height from a datum point for controlling the amount of driving motion of the lifting mechanism 37 at time strains produced in the support lugs 30A to 30D change and stores the height from the datum point as a transfer height for transferring the wafer W between the substrate supporting device and the support lugs 30A to 30D in teaching operations for transferring a wafer W between the substrate supporting device and the support lugs 30A to 30D.

Execution of operations in the teaching mode for teaching the heating module 7 will be described by way of example. In teaching transfer operations for transferring a wafer W between the lifting pins 73 and the support lugs 30A to 30D, operations for transferring a wafer W from the lifting pins 73, namely, the substrate supporting device, to the support arm 3A (support arm 3B), and operations for transferring a wafer W from the support arm 3A (support arm 3B) to the lifting pins 73 are taught.

When a wafer W is transferred from the lifting pins 73 to the support arm 3A (support arm 3B), the support arm 3A (support arm 3B) is advanced along the base 31 to the forward position (the transfer position), and then the support arm 3A (support arm 3B) is raised. Upon the reception of the wafer W from the lifting pins 73 by raising the support arm 3A (support arm 3B), strains measured by the strain gages 4A to 4D change from OFF data to ON data. The counter 39 counts the number of pulses generated by the encoder 38 indicating a height from a datum point for controlling the amount of driving motion of the lifting mechanism 37 at time strains produced in the support lugs 30A to 30D change. The number of pulses indicating a transfer height from the datum point is stored in a storage device, not shown, included in the controller 5.

When a wafer W is transferred from the support arm 3A (support arm 3B) to the lifting pins 73, the support arm 3A (support arm 3B) supporting a wafer W is advanced along the base 31 to the forward position, and then the support arm 3A (support arm 3B) is lowered. Upon the transfer of the wafer W from the lowering support arm 3A (support arm 3B) to the lifting pins 73, strains measured by the strain gages 4A to 4D change from ON date to OFF data. The counter 39 counts the number of pulses generated by the encoder 38 indicating the height from the datum point for controlling the amount of driving motion of the lifting mechanism 37 at time strains produced in the support lugs 30A to 30D change. The number of pulses indicating the transfer height from the datum point is stored in the storage device. A height at which the support arm 3A (support arm 3B) is advanced into the module is determined on the basis of the transfer height.

Thus, the height at which a wafer W is transferred from and to each of the modules can be easily determined. Although the height of a wafer W on the lifting pins 73 in the module can be approximately estimated from design data, the actual height of a wafer W on the lifting pins 73 in the module is different from a design height due to assembling errors produced when the modules are stacked up in layers. Therefore, an actual transfer height in each of the modules needs to be taught accurately to the support arm 3A (support arm 3B). The height of a forward position in the module to which the support arm 3A (support arm 3B) is to be advanced can be known from the actual transfer position. When the wafer carrying devices A1 to A4 of the present disclosure are used, the transfer height at which a wafer W be transferred from the support arm 3A (support arm 3B) to the lifting pins 73 can be determined by lowering the support arm 3A (support arm 3B) supporting the wafer W from a position above the lifting pins 73.

Operations in the alignment mode will be described. The alignment mode is chosen to confirm a transfer position at which a wafer W is to be transferred between the substrate supporting device and the support lugs 30A to 30D.

The alignment program 53 is executed in the alignment mode. The alignment program 53 obtains strains measured by the strain gages 4A to 4D, respectively, when a wafer W is transferred from the substrate supporting device to the support lugs 30A to 30D, makes the display 61 display ON and OFF data respectively corresponding to the strains, makes the display 61 display a decision about whether or not the position of the wafer W on the support lugs 30A to 30D is correct, makes the display 61 display information to the effect that the position of the wafer W on the support lugs 30A to 30D is correct when the wafer W is supported at a correct position on the support lugs 30A to 30D, and then retracts the support arm 3A (support arm 3B) to the rearward position, namely, the idle position. Thus, the alignment program is ended. When the wafer W is supported at a correct position on the support lugs 30A to 30D, all the strains measured by the strain gages 4A to 4D correspond to ON data.

The alarm generator 62 displays an alarm and the retraction of the support arm 3A (support arm 3B) to the rearward position is inhibited when the wafer W is supported at an incorrect position on the support lugs 30A to 30D. When the operator judges that the condition needs repair, the operator may carry out repair work. An alarm displayed by the display 61 indicates information to the effect that the wafer W is at an incorrect position on the support lugs 30A to 30D. When the wafer W is at an incorrect position on the support lugs 30A to 30D, at least one of strains measured by the strain gages 4A to 4D corresponds to OFF data.

For example, a state where a wafer W received from the module is supported on the wafer carrying device is displaced laterally from the correct position is shown in FIG. 11A and a state where a wafer W received from the module is supported on the wafer carrying device is displaced longitudinally from the correct position is shown in FIG. 11B. In those states, strains measured by the two strain gages correspond to OFF data and hence it is decided that the wafer W is supported at incorrect position on the support lugs 30A to 30D, ON and OFF data corresponding to the strains measured by the strain gages 4A to 4D and information to the effect that the wafer W is at an incorrect position are displayed by the display 61, and the retraction of the support arm 3A (support arm 3B) to the rearward position is inhibited.

ON and OFF data are displayed respectively for the strain gages 4A to 4D. In the state shown in FIG. 11A, strains measured by the strain gages 4C and 4D on the left side with respect to the advancing direction of the support arm 3A (support arm 3B) correspond to ON data and those measured by the strain gages 4A and 4B on the right side correspond to OFF data. In such a state, it is presumed that the wafer W is displaced to the left with respect to the advancing direction of the support arm 3A (support arm 3B).

In the state shown in FIG. 11B, strains measured by the strain gages 4B and 4C on the rear side with respect to the advancing direction of the support arm 3A (support arm 3B) correspond to ON data and those measured by the strain gages 4A and 4D on the front side correspond to OFF data. In such a state, it is presumed that the wafer W is displaced to the rear with respect to the advancing direction of the support arm 3A (support arm 3B).

Correction work is executed when a correction program 54 for executing operations in a correction mode is chosen by operating the display 61. When the correction program 54 is chosen, the support arm 3A (support arm 3B) is shook slightly back and forth several times. After a predetermined time such as 0.5 s, has passed since the last move of the support arm 3A (support arm 3B), strains measured by the strain gages 4A to 4D are measured to obtain ON or OFF data. If the strains measured by the three or more strain gages are ON data, it is decided that the wafer W is at a correct position on the support lugs 30A to 30D and the correction work is ended. If strains measured by the two or more strain gages are OFF data, the correction work is repeated.

Operations in the alignment mode are executed when a wafer W is transferred from the support lugs 30A to 30D to the substrate supporting device and when a wafer W is transferred from the substrate supporting device to the support lugs 30A to 30D. Since a state in which a wafer W is supported at an incorrect position on the support lugs 30A to 30D can be found at an early stage, countermeasures can be taken while the displacement of a wafer W is small and hence the position of the wafer W can be easily corrected.

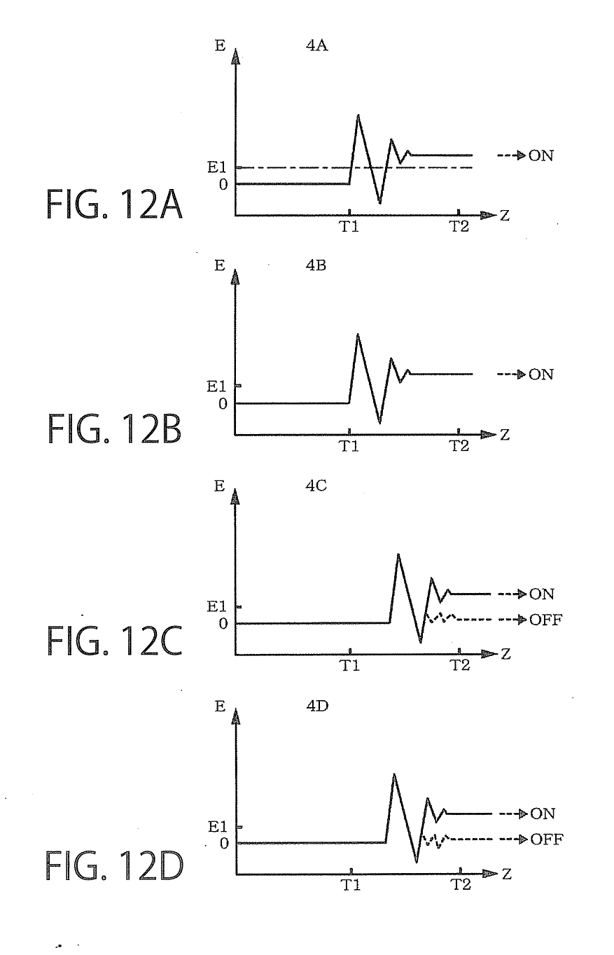

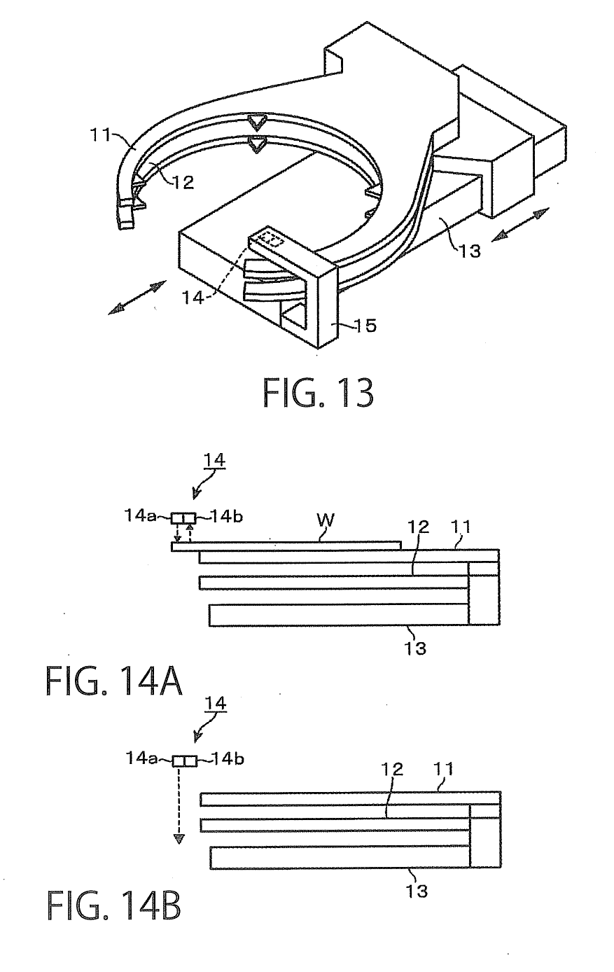

In the alignment mode, strains measured by the strain gages 4A to 4D, namely, voltage signals generated by the strain gages 4A to 4D, may be continuously measured in a period between time T₁ when a wafer W is transferred to the support lugs 30A to 30D of the support arm 3A (support arm 3B) and time T₂ when strains are measured in the inspection mode and the position of the wafer W on the support lugs 30A to 30D may be decided on the basis of the data (strains) thus obtained. In cases illustrated in FIGS. 12A to 12D, a wafer W is seated first on the support lugs 30A and 30B, and then seated on the support lugs 30C and 30D after a delay. When a wafer W is seated on the support lugs 30A to 30D at different times, information may be displayed by the display 61 to the effect that the wafer W is seated at different times on the support lugs 30A to 30D. When such measures are taken, maintenance work or periodic inspection can be executed before abnormal transfer of a wafer W between the substrate supporting device and the support lugs 30A to 30D occurs, and hence accidents can be prevented.

Data shown in FIGS. 12A to 12D may be displayed by the display 61. Values indicated by dotted lines in FIGS. 12C and 12D are obtained when a wafer W once placed on the support lugs 30C and 30D falls off the support lugs 30C and 30D or when the wafer W is warped. In such a case, the data is displayed to facilitate clearing up the causes of supporting the wafer W at an incorrect position on the support lugs 30A to 30D.

According to the present disclosure, the number of the support lugs may be any number not less than three. Some of the support lugs may be not provided with a strain gage, provided that at least three support lugs are provided with strain gages, respectively. The inspection mode, the teaching mode and the alignment mode complete the functions of the wafer carrying devices and enhance the utility of the wafer carrying devices. Only one of the inspection mode, the teaching mode and the alignment mode may be practiced. Only the inspection mode and the teaching mode, the teaching mode and the alignment mode, or the inspection mode and the alignment mode may be practiced.

In the inspection mode, ON data and OFF data obtained from strains measured by the strain gages 4A to 4D, and the data shown in FIGS. 12A to 12D may be displayed by the display 61. The position of a wafer W on the support lugs 30A to 30D may be corrected by choosing the correction mode after the inspection mode.

The substrate carrying device of the present disclosure can be applied not only to the wafer carrying devices A1 to A4 installed in the first block B1 to the fourth block B4, but also to the transfer device C, the transfer arm D, the interface arm F and the shuttle carrier E. The substrate supporting devices include all the devices which receive a wafer W from and transfer a wafer W to the support arm 3A (support arm 3B) including the lifting pins 73 and spin chucks installed in all the modules. A wafer W supported on the support arm 3A (support arm 3B) may be transferred to the substrate supporting device by positioning the support arm 3A (support arm 3B) supporting the wafer W at a position above the substrate supporting device, raising the substrate supporting device, and a wafer W supported on the substrate supporting device may be transferred to the support arm 3A (support arm 3B) by positioning the substrate supporting device supporting the wafer W above the support arm 3A (support arm 3B) and lowering the substrate supporting device. The present disclosure is applicable not only to the resist pattern forming system, but also to all the substrate carrying devices provided with a holding frame and to transfer a wafer W to and to receive a wafer W from the substrate supporting device.

What is claimed is:

1. A substrate carrying device comprising:
a base capable of being driven by a driving unit for vertical movement;
a substrate support arm mounted on the base, capable being driven by a driving unit for longitudinal movement along the base, and shaped so as to surround a substrate;
three or more support members arranged at intervals along an inner edge of the substrate support arm and projecting inward from the inner edge of the substrate support arm to support a substrate thereon;
strain gages attached to the support members, respectively, to measure strains respectively produced in the support members when downward load is placed on the support members;
a decision means for deciding whether or not a substrate is supported in a correct position on the support members on the basis of strains respectively produced in the support members and measured by the strain gages when the substrate is transferred from a substrate supporting device to the support members by advancing the substrate support arm and raising the base relative to the substrate supporting device supporting the substrate; and
a retraction inhibiting means for inhibiting the retraction of the substrate support arm when it is decided that the substrate is supported in an incorrect position on the support members.

2. The substrate carrying device according to claim 1, wherein the decision means compares the strains measured by the strain gages with a threshold determined on the basis of strains measured by the strain gages when a substrate is supported in a correct position on the support members, and decides that the substrate is supported in an incorrect position on the support members when the strain measured by at least one of the strain gages is below the threshold.

3. The substrate carrying device according to claim 2, further comprising a controller which reads a height for controlling an amount of driving motion of the driving unit from a datum point at time strains measured by the strain gages change in teaching transfer operations for transferring a substrate between the support members and the substrate supporting device and stores the height as a substrate transfer height.

4. The substrate carrying device according to claim 1, further comprising a controller which reads a height for controlling an amount of driving motion of the driving unit from a datum point at time strains measured by the strain gages change in teaching transfer operations for transferring a substrate between the support members and the substrate supporting device and stores the height as a substrate transfer height.

5. A substrate carrying method to be carried out by a substrate carrying device comprising: a base capable of being driven by a driving unit for vertical movement; a substrate support arm mounted on the base, capable being driven by a driving unit for longitudinal movement along the base, and shaped so as to surround a substrate; three or more support members arranged at intervals along an inner edge of the substrate support arm and projecting inward from the inner edge of the substrate support arm to support a substrate thereon; to transfer a substrate from and to a substrate supporting device for supporting a substrate thereon; said substrate carrying method comprising the steps of:
receiving a substrate from the substrate supporting device by advancing the substrate support arm and raising the base relative to the substrate supporting device;
measuring strains respectively produced in the support members by strain gages attached to the support members, respectively, when a load is placed on the support members;
deciding whether or not the substrate is supported in a correct position on the support members on the basis of strains measured by the strain gages; and
inhibiting the retraction of the substrate support arm when it is decided that the substrate is supported in an incorrect position on the support members.

6. The substrate carrying method according to claim 5, wherein the step of deciding whether or not a substrate is supported in a correct position on the support members compares the strains measured by the strain gages with a threshold determined on the basis of strains measured by the strain gages when a substrate is supported in a correct position on the support members, and decides that the substrate is supported in an incorrect position on the support members when the strain measured by at least one of the strain gages is below the threshold.

7. A substrate carrying method according to claim 6, further comprising the step of reading a height for controlling an amount of driving motion of the driving unit from a datum position at time strains measured by the strain gages change in teaching transfer operations for transferring a substrate between the support members and the substrate supporting device and storing the height as a substrate transfer height.

8. A substrate carrying method according to claim 5, further comprising the step of reading a height for controlling an amount of driving motion of the driving unit from a datum position at time strains measured by the strain gages change in teaching transfer operations for transferring a substrate between the support members and the substrate supporting device and storing the height as a substrate transfer height.

9. A storage medium storing computer programs to be executed by a substrate carrying device comprising: a base capable of being driven by a driving unit for vertical movement; a substrate support arm mounted on the base, capable being driven by a driving unit for longitudinal movement along the base, and shaped so as to surround a substrate; three or more support members arranged at intervals along an inner edge of the substrate support arm and projecting inward from the inner edge of the substrate support arm to support a substrate thereon; and specifying sets of instructions to be executed in the steps of the substrate carrying method according to claim 5.
